(19) United States
(12) Patent Application Publication
(10) Pub. No.: US 2011/0031622 A1
(43) Pub. Date: Feb. 10, 2011

(54) METHOD FOR FABRICATING SEMICONDUCTOR DEVICE AND SEMICONDUCTOR DEVICE

(76) Inventors: Makoto HONDA, Kanagawa (JP); Junichi Wada, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/853,132

(22) Filed: Aug. 9, 2010

(30) Foreign Application Priority Data
Aug. 10, 2009 (JP) 2009-185449

(51) Int. Cl. H01L 23/498; H01L 21/3205

(52) U.S. Cl. 257/740; 438/653; 257/E21.296; 257/E23.06

(57) ABSTRACT

A method for fabricating a semiconductor device according to an embodiment includes: forming a nickel (Ni) film containing phosphorus (P) elements on a substrate having at least one of a diffusion layer formed by using silicon (Si) and a gate electrode formed by using Si exposed on a surface thereof; and forming a nickel silicide (NiSi) film containing P elements on the substrate from the Ni film containing the P elements and Si in at least one of the diffusion layer and the gate electrode.

### CROSS-REFERENCE TO RELATED APPLICATION

This application is based upon and claims the benefit of priority from prior Japanese Patent Application No. 2009-185449 filed on Aug. 10, 2009 in Japan, the entire contents of which are incorporated herein by reference.

### FIELD

Embodiments described herein relate generally to a method for fabricating a semiconductor device and a semiconductor device.

### BACKGROUND

In recent years, with increases in integration density and performance of a semiconductor integrated circuit (LSI), a diffusion layer of a semiconductor substrate and a gate electrode of a transistor are demanded to have low resistances. In order to respond to the demand, a diffusion layer resistance or a gate electrode resistance is lowered by forming a metal silicide film on the diffusion layer or the gate electrode to provide a salicide structure. As a metal silicide film, a nickel silicide (NiSi) film may be exemplified. For example, a Pt-containing NiSi film is formed on a diffusion layer or a gate electrode so as to lower the diffusion layer resistance or the gate electrode resistance (for example, see Japanese Patent Laying-Open No. 2009-99947).

However, in a conventional NiSi film, the NiSi film is agglomerated or nickel (Ni) atoms move in a silicon (Si) layer in another thermal process for forming a semiconductor device performed after the NiSi film formation step. In particular, such phenomenon often occurs in a thermal process at 450° C. or higher. Due to such phenomenon a Si-rich layer such as NiSi₂ layer is formed in the Si layer. When an Si-rich layer is formed in the Ni silicide layer, a wiring resistance may be increased or a junction leak may occur in a diffusion layer, which has been a problem.

### BRIEF DESCRIPTION OF THE DRAWINGS

FIG. 1 is a flow chart showing a main part of a method for fabricating a semiconductor device according to Embodiment 1.

FIGS. 2A to 2C are step sectional views showing steps performed according to the flow chart of FIG. 1.

FIG. 3 is a conceptual view showing an example of a method of forming a P-containing Ni film according to Embodiment 1.

FIG. 4 is a conceptual view showing another exemplary method of forming a P-containing Ni film according to Embodiment 1.

FIG. 5 is a conceptual view showing another exemplary method of forming a P-containing Ni film according to Embodiment 1.

FIG. 6 is a conceptual view showing another exemplary method of forming a P-containing Ni film according to Embodiment 1.

FIG. 7 is a conceptual view showing another exemplary method of forming a P-containing Ni film according to Embodiment 1.

FIG. 8 is a graph showing P concentration of an NiSi film according to Embodiment 1.

FIG. 9 is a graph showing a result of measuring heat resistance of a Pt-containing NiSi film as a comparison target to be compared with Embodiment 1.

FIGS. 10A and 10B are photos of a section and a surface of the semiconductor device obtained by forming a Pt-containing NiSi film on the diffusion layer as a comparison target when heated to 800° C.

FIG. 11 is a graph showing a result of measuring heat resistance of a P-containing NiSi film according to Embodiment 1.

FIGS. 12A and 12B are photos of sections of the semiconductor device obtained by forming a P-containing NiSi film according to Embodiment 1 on the diffusion layer when respectively heated to 400° C. and 800° C.

FIG. 13 is a graph showing composition ratio of Ni and Si when the P-containing NiSi film according to Embodiment 1 was heated to 800° C.

FIG. 14 is a graph showing comparison of orientations of the P-containing NiSi film according to Embodiment 1 and a conventional NiSi film as a comparison target.

FIGS. 15A to 15D are conceptual views for explaining how Ni atoms move in Embodiment 1 where P is doped and in an embodiment where P is not doped.

### DETAILED DESCRIPTION

### Embodiment 1

A method for fabricating a semiconductor device according to Embodiment 1 includes: next processes. A nickel (Ni) film containing phosphorus (P) elements on a substrate having at least one of a diffusion layer formed by using silicon (Si) and a gate electrode formed by using Si exposed on a surface thereof, is formed. And a nickel silicide (NiSi) film containing P elements on the substrate from the Ni film containing the P elements and Si in at least one of the diffusion layer and the gate electrode, is formed.

The semiconductor device according to Embodiment 1 includes a silicon (Si) substrate, at least one of a diffusion layer and a gate electrode, and a nickel silicide (NiSi) film containing phosphorus (P) elements. The diffusion layer is formed in the Si substrate and the gate electrode formed on the Si substrate using Si. The NiSi film containing P elements is formed on at least one of the diffusion layer and the gate electrode while contacting thereto.

The semiconductor device according to Embodiment 1 includes a silicon (Si) substrate, a gate electrode, a sidewall dielectric film, and a first nickel silicide (NiSi) film containing phosphorus (P) elements. The gate electrode is formed on the Si substrate using Si. The sidewall dielectric film is formed at a position adjacent to a side surface of the gate electrode. The first NiSi film containing P elements is formed on a surface of the gate electrode and a surface of the sidewall dielectric film that is adjacent to the gate electrode excepting parts which do not contact the gate electrode.

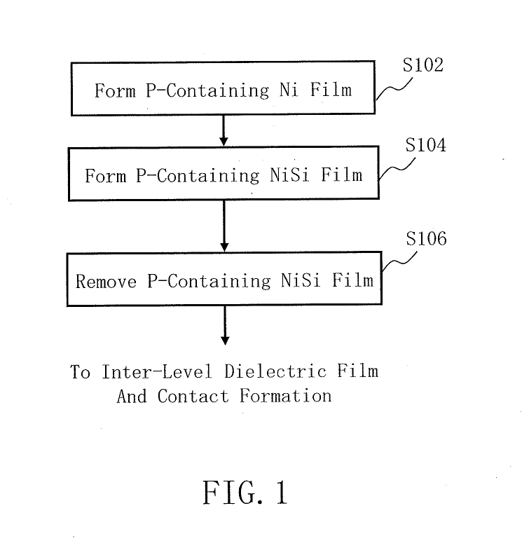

Hereinafter, Embodiment 1 will be explained referring to the accompanying drawings. FIG. 1 is a flow chart showing a main part of a method for fabricating a semiconductor device according to Embodiment 1. In FIG. 1, in the method for fabricating the semiconductor device according to Embodiment 1, a series of steps including: a nickel (Ni) film containing phosphorus (P) elements (phosphorus (P)-containing nickel (Ni) film) formation step (S102); a nickel silicide (Ni) film containing phosphorus (P) elements (phosphorus (P)-containing nickel silicide (Ni) film) formation step (S104); and a P-containing Ni film removing step (S106) is performed.

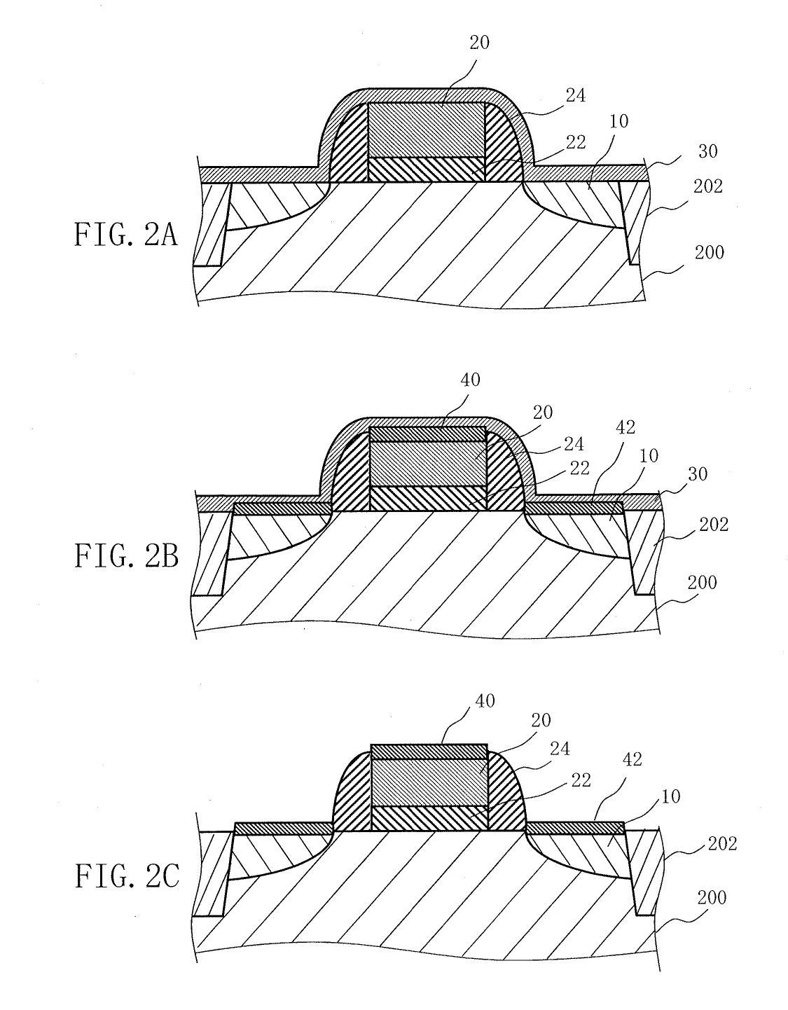

FIGS. 2A to 2C are step sectional views showing steps performed according to the flow chart of FIG. 1. First, a part of a semiconductor device is previously formed on the substrate 200. For example, in the silicon (Si) substrate 200 of p-type, an element isolation dielectric film 202 is formed by Shallow Trench Isolation (STI) technique. Then, a silicon oxide (SiO₂) film as an example to be a material of the gate dielectric film 22 is formed on the substrate 200. In addition, a polysilicon (Si) film as an example to be a material of the gate electrode 20 is formed on the SiO₂ film. Alternatively, amorphous silicon may be preferably used as a material of the gate electrode 20. Next, materials for the gate dielectric film 22 and the gate electrode 20 are selectively left on a part of a region surrounded by the element isolation dielectric film 202 in the silicon substrate 200 of P-type by using lithography technique and etching technique, and other excess materials for the gate region 22 and the gate electrode 20 are removed by etching. In this manner, the gate dielectric film 22 is selectively formed on a part of the region surrounded by the element isolation dielectric film 202 in the silicon substrate 200 of p-type and the gate electrode 20 is selectively formed on the gate dielectric film 22. Then, n-type impurities are injected into the remaining region surrounded by the element isolation dielectric film 202 in the silicon substrates 200 of p-type while using the gate dielectric film 22 and the gate electrode 20 as masks so that n-type extension, which is not shown, is formed. Also, a silicon oxide (SiO₂) film as an example to be a material of the sidewall dielectric film 24 is formed on the substrate 200 on which the gate dielectric film 22 and the gate electrode 20 are formed, and etch back is performed so as to form a sidewall dielectric films 24 on both side surfaces of the gate electrode 20 and the gate dielectric film 22. Then, n-type impurities are ion injected into the n-type extension while using the sidewall dielectric film 24, the gate dielectric film 22, and the gate electrode 20 as masks so that a n-type diffusion layer 10 is formed.

In this manner, the substrate 200 having the diffusion layer 10 of n-type formed by Si and the gate electrode 20 formed by using polysilicon, for example, exposed on the surface thereof is formed. Here, p-type and n-type of the respective layers may be switched. As the substrate 200, a silicon wafer having a diameter of 300 mm, for example, is used.

In FIG. 2A, as a P-containing Ni film formation step (S102), a P element-containing Ni film 30 is formed to have a film thickness of 10 nm, for example, on the substrate 200 having the diffusion layer 10 of Si and the gate electrode 20 formed by using polysilicon exposed on the surface thereof.

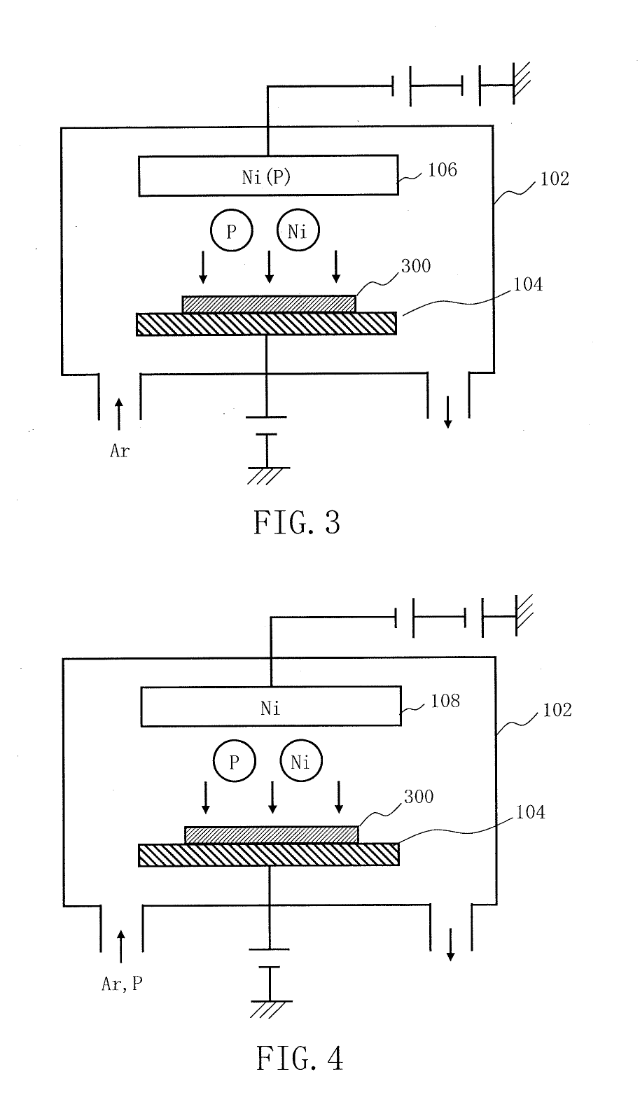

FIG. 3 is a conceptual view showing an example of a method of forming the P-containing Ni film according to Embodiment 1. The P-containing Ni film 30 is preferably formed by physical vapor deposition (PVD) using a Ni target containing P elements, for example. A substrate 300 having the diffusion layer 10 of Si and the gate electrode 20 formed by using polysilicon exposed on the surface thereof as described above is placed on a stage 104 arranged in a chamber 102. A P element-containing Ni target 106 (Ni target containing P elements) is arranged at a position facing the stage 104 in the chamber 102. In such conditions, a predetermined voltage is applied to the target 106 and the substrate 300 while supplying Argon (Ar) so that Ni containing P elements is spattered from the target 106 onto the surface of the substrate 300. Inside of the chamber 102 is evacuated by a vacuum pump, which is not shown, and controlled to be in a desired vacuum atmosphere. Here, heat condition such that the substrate temperature is 200° C. or more, for example, is preferable. Upon spattering, the substrate is heated rather than cooled so that a nickel silicide (NiSi) film to be described later can be formed to have a crystal structure that does not contain (200) orientation and (020) orientation. In the example shown in FIG. 3, negative voltage is applied to the target 106 and positive voltage is applied to the substrate 300, for example. It is obvious that the way to perform such a sputter process is not limited to the example shown in FIG. 3, but the sputter process may be performed using any other technique. In this manner, the P-containing Ni film 30 is formed on the surface of the substrate 300. Alternatively, the P-containing Ni film 30 may be formed by the following method.

FIG. 4 is a conceptual view showing another exemplary method of forming a P-containing Ni film according to Embodiment 1. In FIG. 4, the P-containing Ni film 30 may be also preferably formed by PVD method using a P element-not-containing Ni target 108 (Ni target not containing P elements) and P element-containing gas (gas containing P elements), for example. The method differs from the example shown in FIG. 3 in that the P element-not-containing Ni target 108 is used instead of the P element-containing Ni target 106 and in that the P element-containing gas is added to supply gas. Other configuration is the same as FIG. 3. In this manner, the P-containing Ni film 30 is formed on the surface of the substrate 300. Alternatively, the P-containing Ni film 30 may be formed by the following method.

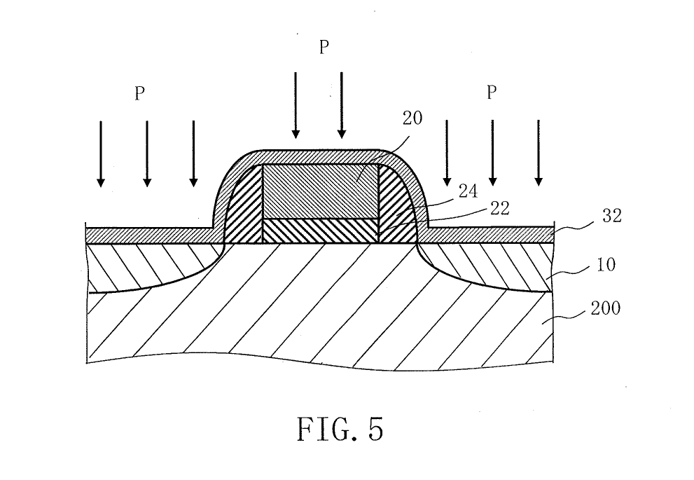

FIG. 5 is a conceptual view showing another exemplary method of forming a P-containing Ni film according to Embodiment 1. In FIG. 5, the P-containing Ni film 30 may be also preferably formed by forming an Ni film 32 by PVD method first and by ion implantation method in which P elements are implanted into the Ni film 32. The way of forming the Ni film 32 by PVD method may be realized by excluding P element from the supply gas in the configuration shown in FIG. 4 described above. Alternatively, the target 108 may be used instead of the target 106 in the configuration shown in FIG. 3 described above. In addition, the Ni film 32 may be formed by chemical vapor deposition (CVD) method to be described later instead of PVD method. After the Ni film 32 is formed, P element is ion-implanted from the above, whereby the P-containing Ni film 30 is formed on the substrate 300. Upon such spattering, heat condition such that the substrate temperature is 200° C. or more, for example, is preferable. The substrate is heated rather than cooled so that an NiSi film to be described later can be formed to have a crystal structure that does not contain (200) orientation and (020) orientation. In this manner, the P-containing Ni film 30 is formed on the surface of the substrate 300. Alternatively, the P-containing Ni film 30 may be formed by the following method.

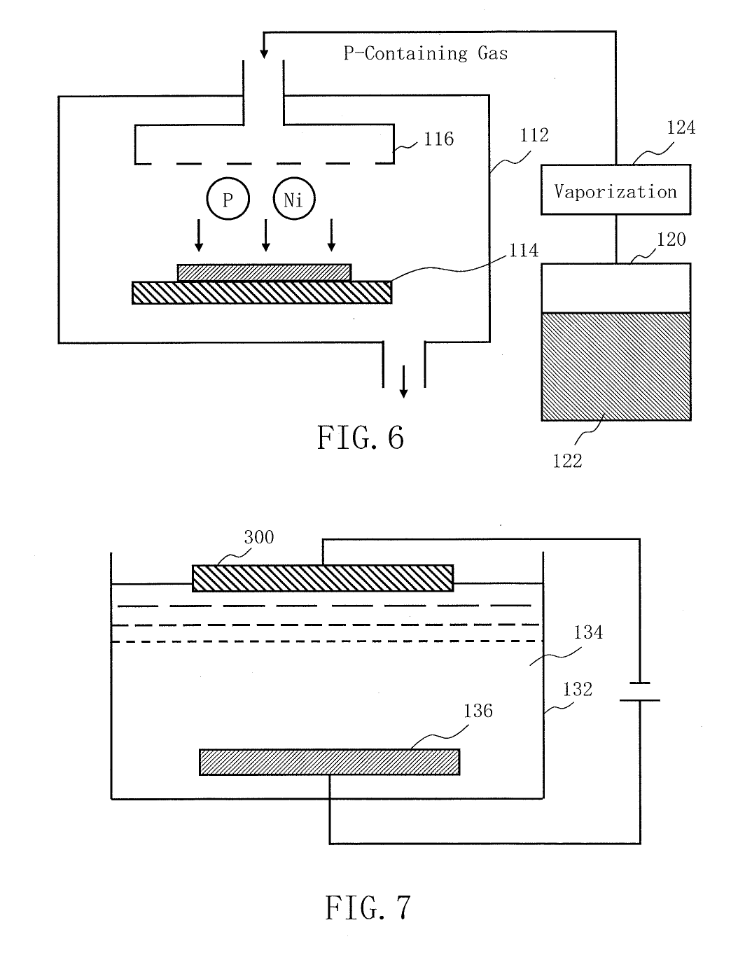

FIG. 6 is a conceptual view showing another exemplary method of forming a P-containing Ni film according to Embodiment 1. In FIG. 6, the P-containing Ni film 30 may be also preferably formed by CVD method using a material containing Ni element and P element. A substrate 300 having the diffusion layer 10 of Si and the gate electrode 20 formed by using polysilicon exposed on the surface thereof as described above is placed on a stage 114 arranged in a chamber 112. A shower head 116 as a supply port to supply process gas is arranged at a position facing the stage 114 in the chamber 112. Inside of the chamber 112 is evacuated by a vacuum pump, which is not shown, and controlled to be in a desired vacuum atmosphere. A container 122 containing liquid or solid raw material containing Ni element and P element 120 is connected to a vaporizer 124 and the raw material 120 is vaporized to be supplied into the chamber 112 through the shower head 116. As the raw material 120, Ni (PF₃)₄, which is liquid at room temperature, for example, may be used. The process temperature is preferably 150° C. or more and more preferably 160 to 240° C. The raw material 120 is not limited to liquid or solid and may be gas as long as the raw material 120 contains Ni element and P element. It is also preferable to use PECVD method using plasma. In this manner, the P-containing Ni film 30 is formed on the surface of the substrate 300. Alternatively, the P-containing Ni film 30 may be formed by the following method.

FIG. 7 is a conceptual view showing another exemplary method of forming a P-containing Ni film according to Embodiment 1. In FIG. 7, the P-containing Ni film 30 may be also preferably formed by Ni plating method using P element-containing liquid (liquid containing P elements). The substrate 300 is immersed in a plating path 132 containing plating solution 134 containing P elements and Ni elements in a state that the surface where the diffusion layer 10 of Si and the gate electrode 20 formed by using polysilicon are exposed as described above faces down (liquid surface). P element may be mixed in the plating solution 134 as an additive, for example. When the electro-plating method is used, an anode electrode 136 is arranged at a position facing the surface of the substrate 300 as a cathode in the plating bath 132. Then, a voltage is applied in such a manner that the surface of the substrate 300 is a negative electrode and the anode electrode 136 is a positive electrode to apply electric current, whereby the P-containing Ni film 30 is formed on the surface of the substrate 300. Alternatively, electroless-plating method may be used instead of electro-plating method. In this case, the anode electrode 136 is not needed.

In FIG. 2B, the substrate 200, on which the P element-containing Ni film 30 is formed, is annealed as the P-containing NiSi film formation step (S104), whereby a P element-containing NiSi film 40 is selectively formed on the contact interface where the P-containing Ni film 30 contacts the polysilicon of the gate electrode 20. At the same time, a P element-containing NiSi film 42 is selectively formed on the contact interface where the P-containing Ni film 30 contacts Si of the diffusion layer 10. In this manner, the P element-containing NiSi films 40 and 42 are selectively formed on the substrate 200 from the P element-containing Ni film 30, Si of the diffusion layer 10, and the Si of the gate electrode 20.

In FIG. 2C, as the P-containing Ni film removing step (S106), the P element-containing Ni film 30 (remaining Ni film containing P elements) formed on the substrate 200 is removed by wet etching method, for example. As an etchant, sulfuric acid hydrogen peroxide mixture is preferably used. In this manner, the P-containing Ni film 30 that has not been used for forming the P element-containing NiSi films 40 and 42 is removed, whereby the P element-containing NiSi film 40 selectively formed on the gate electrode 20 and the P element-containing NiSi film 42 selectively formed on the diffusion layer 10 are exposed. Through the process, the P element-containing NiSi film 40 is formed on the surface of the gate electrode 20 and the surface of the sidewall dielectric film 24 that is adjacent to the gate electrode 20 excepting parts which do not contact the gate electrode 20. Similarly, the P element-containing NiSi film 42 is formed on the surface of the diffusion layer 10 and the surface of the sidewall dielectric film 24 that is adjacent to the diffusion layer 10 excepting parts which do not contact the diffusion layer 10.

By performing each of the steps as described above, a transistor device can be formed. By forming the P element-containing NiSi films 40 and 42, the resistance of the diffusion layer 10 and the wiring resistance of the gate electrode 20 (or gate wire) can be lowered. In addition, if the gate electrode 20 formed in wiring shape is used as a word line of a memory device, the wiring resistance of the word line can be lowered. In addition, a multilayer wiring may be formed by forming an inter-level dielectric film, a contact, and the like on the substrate and then forming a wiring layer as an upper layer.

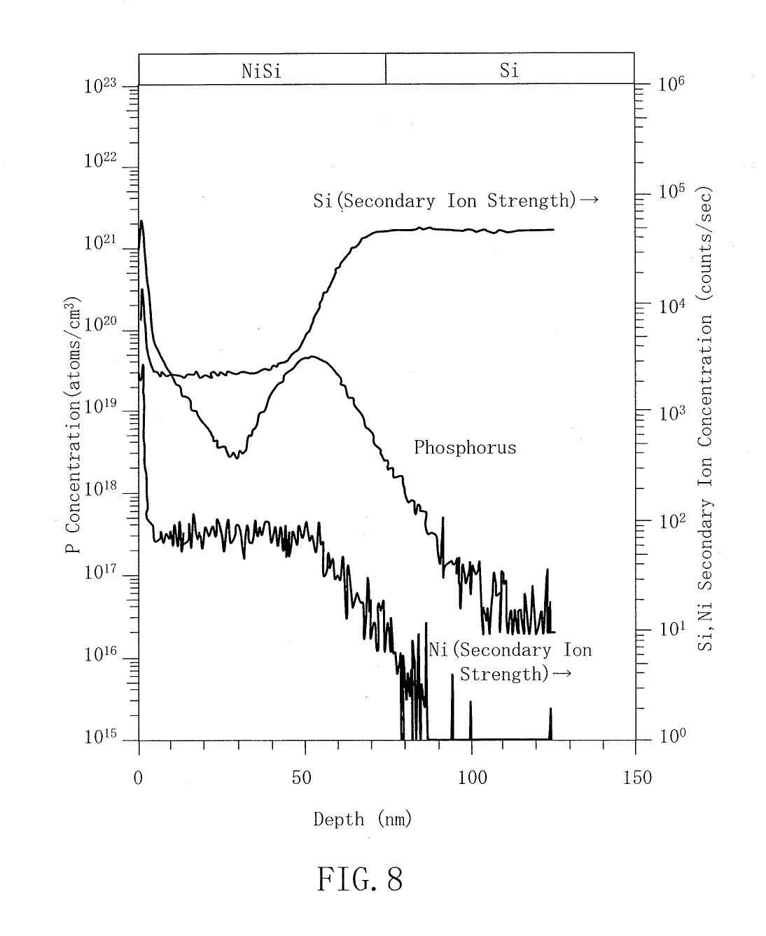

FIG. 8 is a graph showing P concentration of the NiSi film according to Embodiment 1. The element concentration of the substrate after each of the steps described above is performed was measured to find that the NiSi films 40 and 42 formed from the P-containing Ni film 30 also contained P as shown in FIG. 8. Here, the P concentration of the NiSi films is preferably 0.5 wt % or more.

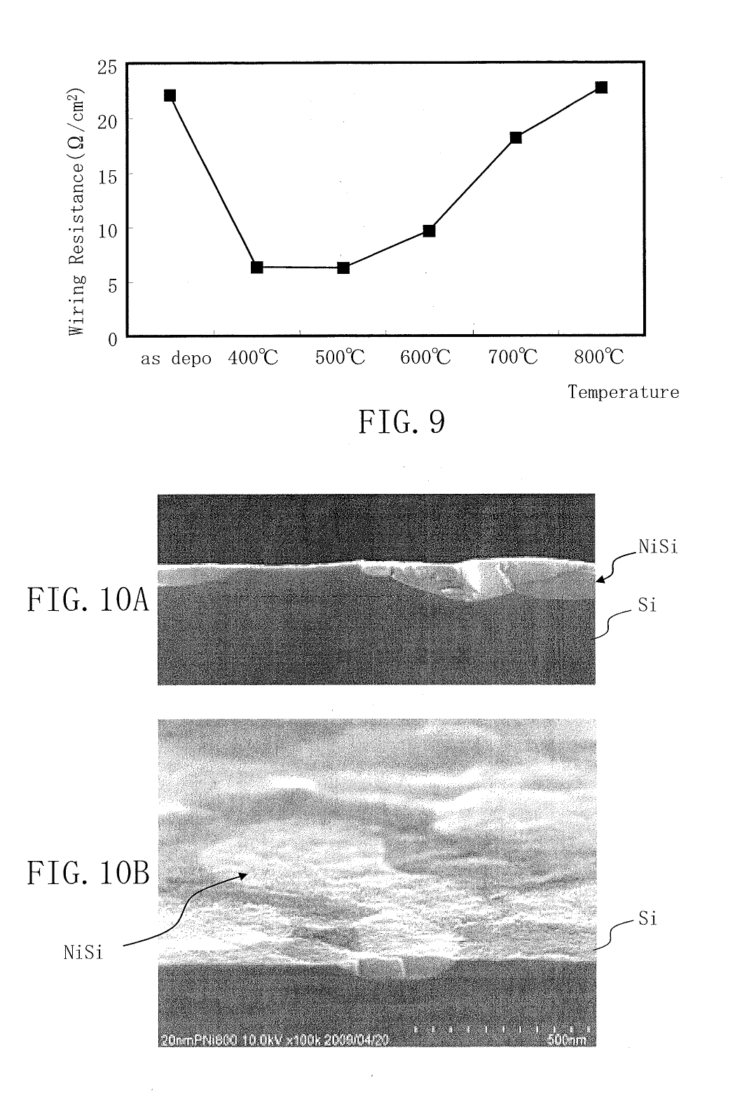

FIG. 9 is a graph showing a result of measuring heat resistance of a Pt-containing NiSi film as a comparison target to be compared with Embodiment 1. The wiring resistance was measured when a conventional semiconductor device obtained by forming a Pt-containing NiSi film on a diffusion layer was heated. As a result, it can be seen that even when Pt was doped in order to increase heat resistance, the wiring resistance increased when heated to more than 500° C. as shown in FIG. 9.

FIGS. 10A and 10B are photos of a section and a surface of the semiconductor device obtained by forming a Pt-containing NiSi film on the diffusion layer as a comparison target when heated to 800° C. FIG. 10A shows the section. FIG. 10B shows the surface. The Pt-containing NiSi film was agglomerated when heated to 800° C. and a part where the film thickness was locally large and a part where the film thickness was almost zero were found on Si as shown in FIG. 10A. Also on the surface, a part where the Pt-containing NiSi film did not exist and the Si film was exposed due to the agglomeration was found. When the Pt-containing NiSi film does not exist (film breaking occurs), the wiring resistance is increased. In addition, when the Pt-containing NiSi film is agglomerated to a part to make the part have a large film thickness, the Pt-containing NiSi film protrudes through the diffusion layer to reach p-type Si region so as to cause a junction leak. In addition, if the Pt-containing NiSi film does not protrude through the diffusion layer, the thickness of the Si region in the diffusion layer is decreased, and thus a junction leak may easily occur. Consequently, it was found that sufficient heat resistance cannot be obtained with the Pt-containing NiSi film as the comparison target.

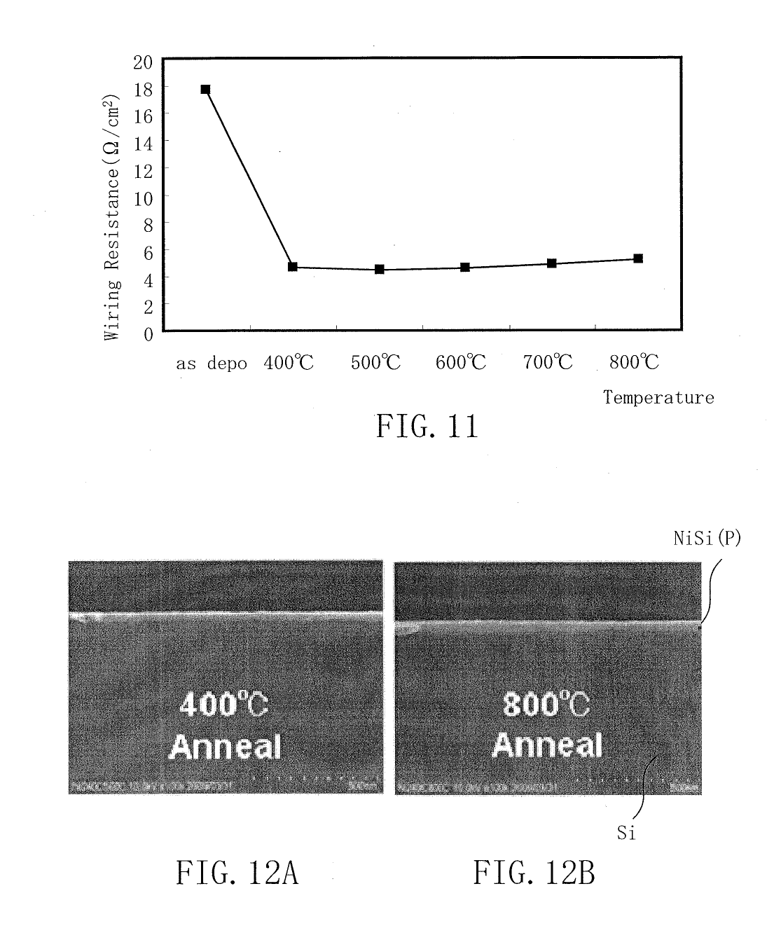

FIG. 11 is a graph showing a result of measuring heat resistance of a P-containing NiSi film according to Embodiment 1. The wiring resistance was measured when a semiconductor device obtained by forming the P-containing NiSi film 42 according to Embodiment 1 on a diffusion layer was heated. As a result, it can be seen that the wiring resistance increased very little even at 800° C. as shown in FIG. 11.

FIGS. 12A and 12B are photos of sections of the semiconductor device obtained by forming a P-containing NiSi film according to Embodiment 1 on the diffusion layer when respectively heated to 400° C. and 800° C. FIG. 12A shows the section of the semiconductor device when heated to 400° C. FIG. 12B shows the section of the semiconductor device when heated to 800° C. In both cases, the P-containing NiSi film 42 of the predetermined film thickness was found and agglomeration was not found. As confirmed above, when the NiSi film contains P, the heat resistance can be substantially increased comparing to the conventional semiconductor device.

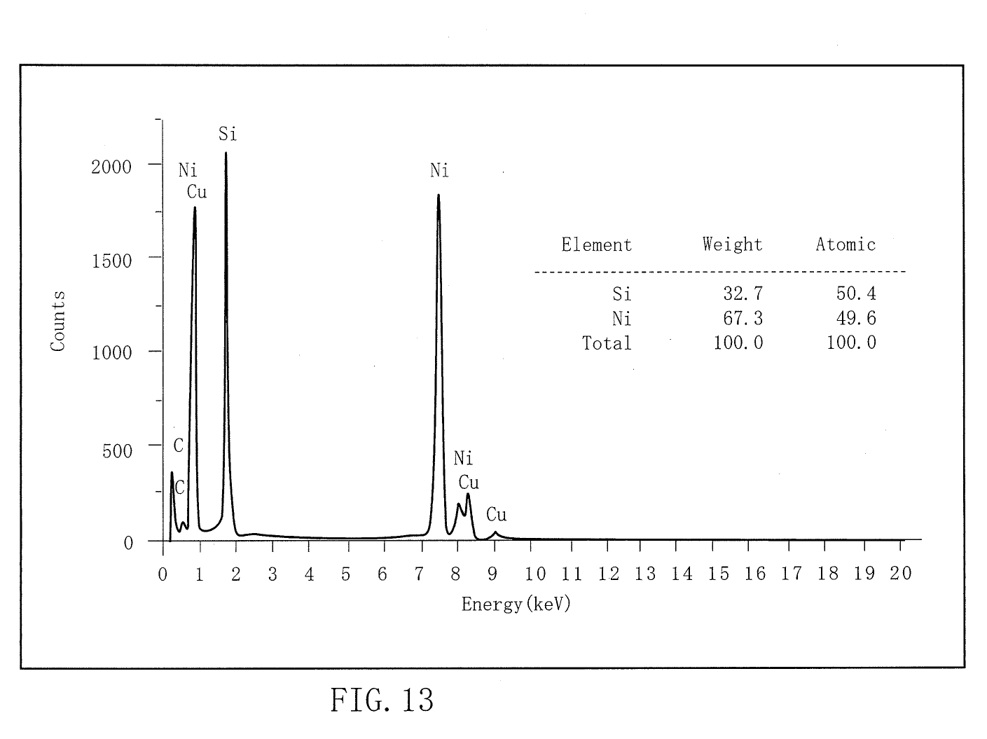

FIG. 13 is a graph showing composition ratio of Ni and Si when the P-containing NiSi film according to Embodiment 1 was heated to 800° C. From the result of the EDX analysis shown in FIG. 13, it can be seen that the composition ratio of Ni and Si was 1:1 even when the P-containing NiSi film was heated to 800° C. Therefore, it can be found that the P-containing NiSi film was not Si-rich such as NiSi₂ and remained to be monosilicide.

In addition, the inventors found that the heat resistance can be increased by controlling the orientation of the crystal structure of the P-containing NiSi film.

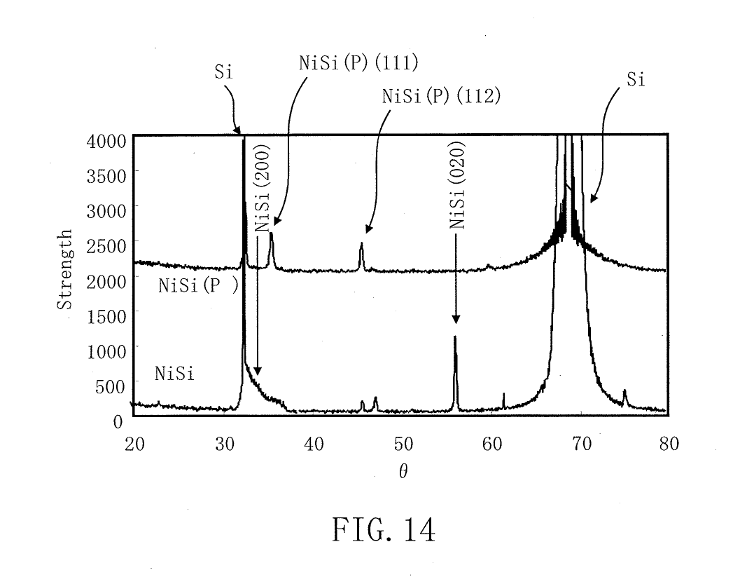

FIG. 14 is a graph showing comparison of orientations of the P-containing NiSi film according to Embodiment 1 and a conventional NiSi film as a comparison target. As a result of comparing the orientations of the P-containing NiSi film according to Embodiment 1 and the conventional NiSi film having insufficient heat resistance as a comparison target by X-ray diffraction, the crystal of the conventional NiSi film has, in particular, (200) orientation and (020) orientation as shown in FIG. 14 among various orientations. On the other hand, in the P-containing NiSi film having the increased heat resistance according to Embodiment 1, the (200) orientation and the (020) orientation do not exist. Through the dedicated investigation, the inventors found that the heat resistance of the NiSi film can be increased by controlling the NiSi film to have the crystal structure that does not have the (200) orientation and the (020) orientation.

Therefore, in Embodiment 1, the P-containing NiSi film is controlled to have the crystal structure that does not have at least one of the (200) orientation and the (020) orientation upon forming the P-containing NiSi film. The P-containing NiSi film can be controlled to have the crystal structure that does not have the (200) orientation or the (020) orientation by adjusting the temperature upon forming the P-containing Ni film 30 before silicided as described above, for example. More specifically, in sputter process, the control can be achieved by forming the P-containing Ni film 30 or Ni film 32 while heating the substrate to 200° C. or more, for example. Alternatively, in CVD method, the control can be achieved by forming the P-containing Ni film 30 or Ni film 32 at the process temperature of 160 to 240° C.

In the example described above, a case where both of the diffusion layer 10 formed in the Si substrate and the gate electrode 20 formed on the Si substrate using Si are formed is explained, but it is obvious that forming only either one is effective in view of lowering the wiring resistance. Therefore, the semiconductor device according to Embodiment 1 can be configured by including: the Si substrate; at least one of the diffusion layer 10 formed in the Si substrate and the gate electrode 20 formed on the Si substrate using Si; and the P element-containing NiSi film 40 or 42 formed on the at least one of the diffusion layer 10 and the gate electrode 20 to contact thereto.

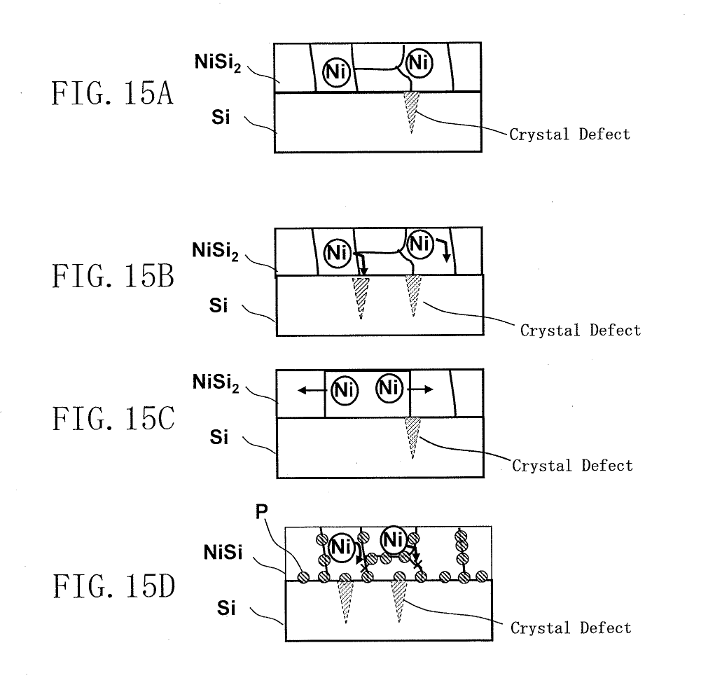

FIGS. 15A to 15D are conceptual views for explaining how Ni atoms move in Embodiment 1 where P is doped and in an embodiment where P is not doped. FIGS. 15A to 15C show a case where P is not doped. FIG. 15D shows a case where P is doped. After a nickel silicide layer is formed on Si layer without doping P as shown in FIG. 15A, Ni atoms move as shown in FIG. 15B or 15C due to a thermal process in a later step, and thus NiSi₂ layer, which is silicon rich, is formed. On the other hand, when a nickel silicide layer is formed while doping P according to Embodiment 1, even when a thermal process is performed in a later step after the nickel silicide layer is formed on Si layer, Ni is prevented from moving since P elements exist on the crystal grain boundary as shown in FIG. 15D, for example. Therefore, NiSi is not easily agglomerated. P elements are dispersed over the entire nickel silicide layer, but many of them exist on the crystal grain boundary in the nickel silicide layer when the thermal process in a later step is performed at particularly high temperature.

As described above, according to the embodiment, the NiSi film having the increased heat resistance can be formed on the diffusion layer and the gate electrode. As a result, the increase of the wiring resistance and the junction leak in the diffusion layer may be suppressed.

The embodiment is explained with reference to the concrete examples. However, the invention is not limited to the concrete examples. The P element-containing NiSi film 40 is preferably formed over the entire surface of the diffusion layer 10 formed by using Si. As a result, the effect of suppressing the junction leak is further improved. Similarly, the P element-containing NiSi film is formed over the entire surface of the gate electrode 20 formed by using Si. As a result, the effect of suppressing the increase of the wiring resistance is further improved.

In addition, the film thickness, size, and shape of each of the layers or the films, and the number of the layers or the films, may be appropriately selected for a semiconductor integrated circuit or a semiconductor device of various types.

In addition, all semiconductor devices and all methods for fabricating a semiconductor device which include the elements of the present invention and can be arbitrarily changed in design by those skilled in the art are included in the spirit and scope of the invention.

In addition, to simplify the description, methods that are generally used in semiconductor industry including photolithography process, cleaning before and after each process, for example are not described. However, it is obvious that those methods can be included.

While certain embodiments have been described, these embodiments have been presented by way of example only, and are not intended to limit the scope of the inventions. Indeed, the novel method for fabricating a semiconductor device and semiconductor device described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A method for fabricating a semiconductor device, the method comprising:
forming a nickel (Ni) film containing phosphorus (P) elements on a substrate having at least one of a diffusion layer formed by using silicon (Si) and a gate electrode formed by using Si exposed on a surface thereof; and
forming a nickel silicide (NiSi) film containing P elements on the substrate from the Ni film containing the P elements and Si in at least one of the diffusion layer and the gate electrode.

2. The method according to claim 1, wherein the Ni film containing the P elements is formed by using one of a first physical vapor deposition (PVD) method using a Ni target containing P elements, a second PVD method using a Ni target not containing P elements and a gas containing P elements, an ion implantation method in which after a Ni film is formed and then P elements is implanted into the Ni film, a chemical vapor deposition (CVD) method using a material containing Ni elements and P elements, and a Ni plating method using a liquid containing P elements.

3. The method according to claim 1, wherein the NiSi film containing the P elements is formed to have a crystal structure that does not have at least one of (200) orientation and (020) orientation.

4. The method according to claim 1 further comprising removing a remaining Ni film of the Ni film after forming the NiSi film.

5. The method according to claim 4, wherein P elements contained in the remaining Ni film are also removed when removing the remaining Ni film.

6. The method according to claim 5, wherein when removing the remaining Ni film, a part that has not been used for forming the NiSi film, in the Ni film, is removed as the remaining Ni film.

7. The method according to claim 1, wherein a concentration of P elements contained in the NiSi film is 0.5 wt % or more.

8. The method according to claim 1, wherein the Ni film containing the P elements is formed on the substrate that is heated when forming the Ni film containing the P elements.

9. The method according to claim 8, wherein the Ni film containing the P elements is formed on the substrate that is heated by physical vapor deposition (PVD) using a Ni target containing P elements when forming the Ni film containing the P elements.

10. The method according to claim 1,
wherein when forming the Ni film containing the P elements,
a Ni film not containing P elements is formed by physical vapor deposition (PVD) using a Ni target not containing a P element, and
after the Ni film not containing P elements is formed, P elements are implanted into the Ni film not containing P elements by ion implantation method.

11. A semiconductor device comprising:
a silicon (Si) substrate;
at least one of a diffusion layer formed in the Si substrate and a gate electrode formed on the Si substrate using Si; and
a nickel silicide (NiSi) film containing phosphorus (P) elements formed on at least one of the diffusion layer and the gate electrode while contacting thereto.

12. The device according to claim 11, wherein the NiSi film containing the P elements is formed to have a crystal structure that does not have at least one of (200) orientation and (020) orientation.

13. The device according to claim 11, wherein the NiSi film containing the P elements is formed over an entire surface of at least one of the diffusion layer and the gate electrode.

14. A semiconductor device comprising:
a silicon (Si) substrate;
a gate electrode formed on the Si substrate using Si;
a sidewall dielectric film formed at a position adjacent to a side surface of the gate electrode; and
a first nickel silicide (NiSi) film containing phosphorus (P) elements formed on a surface of the gate electrode and a surface of the sidewall dielectric film that is adjacent to the gate electrode excepting parts which do not contact the gate electrode.

15. The device according to claim 14, wherein the first NiSi film containing P elements is formed over an entire surface of the gate electrode.

16. The device according to claim 14, wherein the first NiSi film containing P elements is formed to have a crystal structure that does not have at least one of (200) orientation and (020) orientation.

17. The device according to claim 14, wherein the gate electrode serves as a word line of a memory device.

18. The device according to claim 14 further comprising:
a diffusion layer formed in the sSi substrate; and
a second NiSi film containing P elements formed on the diffusion layer.

19. The device according to claim 18, wherein the P element-containing second NiSi film is formed over an entire surface of the diffusion layer.

20. The device according to claim 18, wherein the second NiSi film containing the P elements is formed to have a crystal structure that does not have at least one of (200) orientation and (020) orientation.
